(19) United States
(12) Patent Application Publication
(10) Pub. No.: US 2024/0321889 A1
(43) Pub. Date: Sep. 26, 2024

(54) COMPLEMENTARY FIELD EFFECT TRANSISTOR CELLS AND METHODS OF FABRICATING THE SAME

(71) Applicant: IMEC VZW, Leuven (BE)

(72) Inventors: Gaspard Hiblot, Leuven (BE); Gioele Mirabelli, Leuven (BE)

(21) Appl. No.: 18/608,650

(22) Filed: Mar. 18, 2024

(30) Foreign Application Priority Data
Mar. 22, 2023 (EP) 23163364.5

(51) Int. Cl. H01L 27/092; H01L 21/822; H01L 21/8238; H01L 23/528; H01L 29/06; H01L 29/423; H01L 29/66; H01L 29/775

(52) U.S. Cl. CPC H01L 27/0922; H01L 21/8221; H01L 21/823871; H01L 23/5286; H01L 29/0673; H01L 29/42392; H01L 29/66439; H01L 29/775

(57) ABSTRACT

The disclosed technology generally relates to a complementary field effect transistor (CFET) cell. In one aspect, the CFET cell includes: a first transistor structure arranged in a first tier of the CFET cell; a second transistor structure arranged in a second tier of the CFET cell above the first tier; a set of top signal routing lines formed in a first metal layer above the second tier and connected to the first and the second transistor structures from above; and at least one bottom signal routing line formed in a second metal layer below the first tier and connected to the first transistor structure from below. The disclosed technology also generally relates to a method of fabricating a CFET cell.

### CROSS-REFERENCE TO RELATED APPLICATIONS

This application claims foreign priority to European Patent Application No. EP 23163364.5, filed Mar. 22, 2023, the content of which is incorporated by reference herein in its entirety.

### BACKGROUND

### Technical Field

The disclosed technology generally relates to complementary field effect transistor (CFET) devices. For example, the disclosed technology relates to routability of stacked transistor structures in a CFET cell. The disclosed technology presents a CFET cell with a specifically designed signal routing structure, a CFET device that includes such a CFET cell, e.g., at least two of these CFET cells, as well as a method of fabricating such a CFET cell.

### Description of the Related Technology

In a CFET device, different transistor structures, for example, N-Channel Metal-Oxide-Semiconductor (NMOS) and P-Channel Metal-Oxide-Semiconductor (PMOS) transistor structures, may be stacked on top of each other. Compared, for example, to a nanosheet device, which comprises NMOS and PMOS transistor structures arranged side by side with a spacing in between them, the stacking of the transistor structures can enable increasing an effective channel width.

A CFET device may include one or more CFET (unit) cells. An example implementation of a CFET cell may comprise two NMOS transistor structures and two PMOS transistor structures which are processed in a stacked manner.

An issue in a CFET device is related to the connections of the transistor structures, for example, their connections to the power rails and to the signal routing lines.

For example, it can be difficult to connect the bottom device contacts in CFET, because they are shadowed by the top device in the center of the standard cell. Typically, they can only be accessed at the edges of the standard cell. In addition, if two parallel bottom contacts are to be connected, tall vias (e.g., high aspect vias) are used to connect them from the top metal level whose orientation is perpendicular to the bottom contacts.

This situation can become even worse when using a top power rail to provide power to the top device, as the top power rail can occupy one edge of the standard cell. Generally, only the single edge opposing the top power rail can be used to access the bottom device contacts, hence it becomes challenging to route some types of standard cells.

### SUMMARY OF CERTAIN INVENTIVE ASPECTS

It is an objective of the disclosed technology to provide an improved CFET cell and an improved method of fabricating a CFET cell. In various implementations, the above-mentioned disadvantages can be avoided.

The objective can be achieved by various embodiments provided in the enclosed independent claims. Advantageous implementations of the embodiments of the disclosed technology are further defined in the dependent claims.

A first aspect of the disclosed technology can provide a CFET cell, comprising: a first transistor structure arranged in a first tier of the CFET cell; a second transistor structure arranged in a second tier of the CFET cell above the first tier; a set of top signal routing lines formed in a first metal layer above the second tier and connected to the first and the second transistor structure from above; and at least one bottom signal routing line formed in a second metal layer below the first tier and connected to the first transistor structure from below.

This can achieve in various implementations, the advantage that a more compact CFET cell design is provided in which the bottom transistor structure can be contacted via a dedicated bottom signal routing line. For example, the bottom signal routing line can be “tucked” under a gate extension of the CFET cell and thus may not lead to an enlargement of the CFET cell, while more complex (bi-directional) side routing structures may run around the gate extension, causing an extra area penalty.

Furthermore, the CFET cell can be easier to fabricate compared to CFET cells with more complex, e.g., two- or three-dimensional side routing structures. This can be, in various implementations, due to a simpler alignment of a one-dimensional signal routing line during fabrication as compared to more complex (side) routing structures.

One or more transistor structures arranged in the first tier and one or more transistor structures arranged in the second tier may result in stacked transistor structures of the CFET cell. However, two particular transistor structures of the CFET cell-one in the first tier and the other one in the second tier-do not have to be arranged directly above each other (with respect to a stacking direction of the CFET cell, typically the “vertical” direction in this disclosure), but may also be arranged indirectly above each other, which means that they may be offset in a “horizontal” direction, which is perpendicular to the “vertical” or stacking direction. The CFET cell may comprise further transistor structures or other elements, which could respectively be directly above or beneath the first and second transistor structure.

In this disclosure the terms “below” and “above”, “bottom” and “top”, or similar terms can be interpreted relative to each other. For example, these terms can describe opposite sides of the CFET cell, or opposite sides of any element of the CFET cell. The terms may describe a relationship of elements (e.g., transistor structures, signal routing lines, power rails, etc.) of the CFET cell along the direction of stacking of the tiers. The stacking direction may align with the arrangement of the two tiers (or even more than two tiers) of the CFET cell. For example, the two or more tiers, which are arranged above each other, are arranged one after the other along a certain direction (the stacking direction). The relative terms could also be swapped. For instance, in the CFET cell of the first aspect, the set of top signal routing lines is placed at the top side of the CFET cell (e.g., above the second tier), while the at least one bottom signal routing line is placed at the bottom side of the CFET cell (e.g., below the first tier). However, the set of top signal routing lines could also be considered being at the bottom side of the CFET cell (e.g., below the first tier), and the bottom signal routing line(s) could be considered being at the top side of the stacked CFET cell (e.g., above the second tier).

A transistor structure in the disclosed technology may be or may comprise a transistor, for example, a field effect transistor (FET), or may be or may comprise a more complex semiconductor-based structure, which functions like a transistor. For instance, the semiconductor-based structure may be a nanosheet structure, a fin structure, or a forksheet structure, for example, provided with a gate partly wrapping around or fully wrapping around channel portions. The latter may be, for instance, a gate-all-around structure. The transistor structures of the CFET cell of the first aspect may be NMOS and PMOS transistor structures. For instance, the first transistor structure may be an NMOS transistor structure and the second transistor structure a PMOS transistor structure, or vice versa.

A set of elements in the disclosed technology may comprise one or more of the elements. For instance, the set of top signal routing lines may comprise one or more top signal routing lines, for example, three or four top signal routing lines.

The top signal routing lines may be formed in a metal intermediate (Mint) layer, e.g., the first metal layer may be a Mint layer. The Mint layer may be a horizontal metal layer in the CFET cell. The first metal layer of the top signal routing lines may be independent of and/or different from the second metal layer of the bottom signal routing line(s).

The bottom signal routing line can be a buried horizontal local interconnect which is, e.g., introduced in the empty space below the bottom (e.g., first) transistor structure, for instance, next to a back-side contact of the first transistor structure. The bottom signal routing line can provide horizontal routability to the first transistor structure polarity, e.g., to connect N-junctions and/or P-junctions.

In an implementation, the bottom signal routing line is a one-dimensional line structure, and/or is configured to route signals along one spatial direction.

For example, the bottom signal routing line being one-dimensional can refer to it extending along one spatial direction and is spatially confined in all other spatial directions. This can achieve the advantage that it can be easier to align to other structures of the CFET cell during fabrication, for example, during lithographic fabrication.

In an implementation, the bottom signal routing line extends along a direction which is perpendicular to a gate of the first transistor structure and/or to a gate of the second transistor structure.

For example, the bottom signal routing line runs parallel to one or more channels (e.g., parallel to the fin direction) of the first transistor structure.

In an implementation, the bottom signal routing line is connected to one or more metal zero (M0) layer contacts of the first transistor structure, wherein each M0 layer contact is connected to a source or a drain of the first transistor structure.

For example, the connections of the bottom signal routing line to the M0 layer contacts can be established by short vertical contact sections, such as vias.

In an implementation, the CFET cell further comprises a first power rail arranged below the first tier and connected to the first transistor structure from below. For example, the at least one bottom signal routing line is arranged above the first power rail and below the first transistor.

In an implementation, the CFET cell further comprises a second power rail formed in a third metal layer and connected to the second transistor structure from a first side.

The first and the second power rails may be rails for VDD (a supply voltage) and VSS (a ground voltage or negative voltage). For instance, the first power rail may be configured to supply VDD, e.g., is a VDD rail, and the second power rail may be configured to supply VSS, e.g., is a VSS rail. VDD and VSS can be swapped, e.g., if NMOS and PMOS are swapped as well for the first transistor structure and the second transistor structure.

The second power rail being connected to the second transistor structure from the first side may simplify connections of the second transistor structure to the second power rail, e.g., without the need for any deep etch processing and/or the use of high aspect-ratio vias in various implementations. This also may allow leveraging the first power rail as a back-side power rail. The CFET cell of the first aspect is further scalable in track height, e.g., without penalizing routing resources and active area in various implementations.

For example, a part of the second power rail is arranged in the second tier to the first side of the second transistor structure; and/or a part of the second power rail is arranged in the first tier to the first side of the first transistor structure.

In an implementation, the second power rail extends vertically to a bottom side or to a top side of the CFET cell.

In this case, for instance, the CFET cell typically comprises one bottom signal routing line which is arranged on a side opposite to the second power rail.

In an implementation, the top signal routing lines of the set of top signal routing lines are arranged side by side, and a part of the second power rail is arranged to (e.g., on) the first side of the set of top signal routing lines.

For example, the second power rail can have a width that is equal to or larger than two times a critical dimension of the first metal layer.

A second aspect of the disclosed technology can provide a device comprising two CFET cells according to the first aspect of the disclosed technology, wherein the two CFET cells are arranged side by side.

For example, the second power rail of the two CFET cells can be the same power rail, which is arranged between the transistor structures of one CFET cell and the transistor structures of the other CFET cell.

A third aspect of the disclosed technology can provide a method of fabricating a complementary field effect transistor (CFET) cell, comprising: forming a first transistor structure in a first tier of the CFET cell; forming a second transistor structure in a second tier of the CFET cell above the first tier; processing a set of top signal routing lines in a first metal layer above the second tier and connecting the set of top signal routing lines to the first and the second transistor structure from above; and processing at least one bottom signal routing line in a second metal layer below the first tier and connecting the bottom signal routing line to the first transistor structure from below.

In various implementations, the method of the third aspect can achieve the same advantages as the CFET cell of the first aspect, and may be extended by respective implementations as described above for the CFET cell of the first aspect.

The method of the third aspect do not have to be performed, necessarily, in the order in which they are described above. For instance, the bottom signal routing line(s) can be processed prior to the set of top signal routing lines. However, it is also possible to process the top signal routing lines first for example, when the bottom signal routing line is processed from the bottom side.

In an implementation, the bottom signal routing line is processed by etching a trench in a dielectric layer of the CFET cell and subsequently filling the bottom of the trench with the second metal layer.

For instance, the bottom signal routing line can be processed in this way after an active patterning and an STI (shallow trench isolation) planarization of the CFET cell.

In an implementation, to fill the bottom of the trench with the second metal layer, the second metal layer is deposited in the trench and subsequently partially recessed in order to confine the second metal layer to the bottom of the trench below the first tier.

In an implementation, the method further comprises: processing one or more metal zero (M0) layer contacts of the first transistor structure, wherein each M0 layer contact is connected to a source or a drain of the first transistor structure; and connecting the bottom signal routing line to the M0 layer contacts.

In an implementation, the method further comprises: processing a first power rail below the first tier and connecting the first power rail to the first transistor structure from below.

In an implementation, the method further comprises: processing a second power rail in a third metal layer to a first side of the second transistor structure and connecting the second power rail to the second transistor structure.

### BRIEF DESCRIPTION OF THE DRAWINGS

The above described aspects and implementations are explained in the following description of embodiments with respect to the enclosed drawings:

FIG. 1 shows an example CFET cell according to the disclosed technology in a side view;

FIG. 2 shows a first transistor structure of an example CFET cell according to the disclosed technology in a top view;

FIGS. 3A-B show an example CFET cell according to the disclosed technology in a perspective view;

FIG. 4 shows an equivalent circuit diagram of an example CFET cell according to the disclosed technology;

FIG. 5 shows an example CFET cell according to the disclosed technology in a side view;

FIG. 6 shows an example device comprising two CFET cells according to the disclosed technology;

FIGS. 7A-D show various intermediate structures of an example method of fabricating a CFET cell according to the disclosed technology; and

FIG. 8 shows various intermediate structures of an example method of fabricating a CFET cell according to the disclosed technology.

### DETAILED DESCRIPTION OF CERTAIN ILLUSTRATIVE EMBODIMENTS

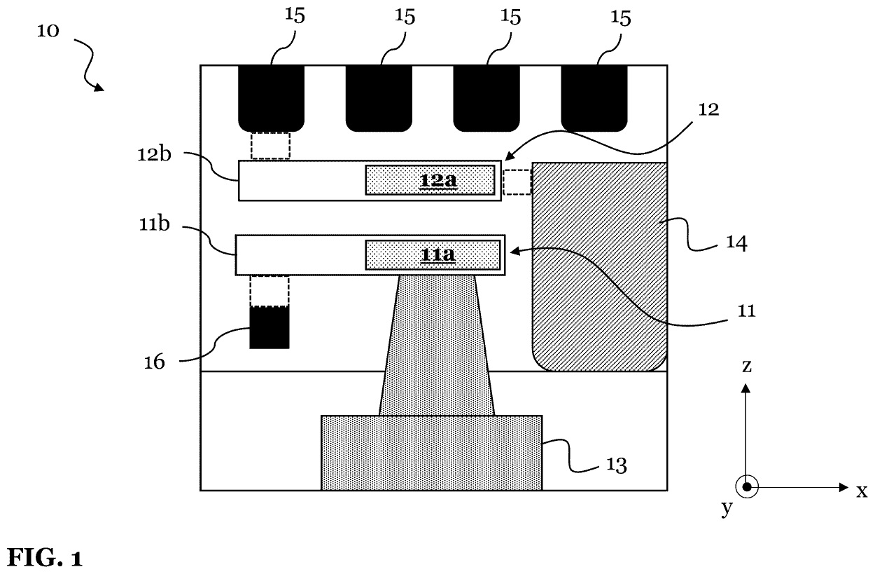

FIG. 1 shows an example CFET cell 10 according to this disclosure in a side view. The CFET cell 10 comprises: a first transistor structure 11 arranged in a first tier of the CFET cell 10; a second transistor structure 12 arranged in a second tier of the CFET cell 10 above the first tier; a set of top signal routing lines 15 formed in a first metal layer above the second tier and connected to the first and the second transistor structure 11, 12 from above; and at least one bottom signal routing line 16 formed in a second metal layer below the first tier and connected to the first transistor structure 11 from below.

As described herein, above/below can correspond to a (“vertical”) z-direction in FIG. 1 which may correspond to a stacking/fabrication direction of the CFET cell 10. For example, FIG. 1 does not show a cross-section of the CFET cell 10, so that the second transistor structure 12 is not necessarily directly above the first transistor structure 11, but in fact may be offset from or shifted with respect to (in this case into the plane of FIG. 1) the first transistor structure 11. The CFET cell 10 may comprise further transistor structures or other elements/components, which are not shown in FIG. 1.

The CFET cell 10 shown in FIG. 1 may be a unit cell of a CFET device, wherein unit cell can mean that the CFET cell 10 could be repeated one or more times in the CFET device. For instance, multiple CFET cells 10 could be arranged side by side, or one above the other, or both. FIG. 1 shows particularly a side view of the CFET cell 10.

The first transistor structure 11 and the second transistor structure 12 can each comprise one or more channels 11a, 12a which in FIG. 1 extend in a y-direction, perpendicular to the x-z plane. For instance, each of the one or more channels 11a, 12a can form a channel stack. The channels 11a, 12a can be silicon (Si) channels.

The first transistor structure 11 can comprise one or more metal zero (M0) layer contacts 11b. The M0 layer contact(s) 11b can be connected to a source/drain of the first transistor structure 11 and/or can merge into the source/drain of the first transistor structure 11.

The bottom signal routing line 16 can be connected to the M0 layer contact 11b from the bottom side. This connection can be established by vertical contact sections, illustrated by a dashed box in FIG. 1. In this way, the bottom signal routing line 16 can be connected to a source and/or drain of the first transistor structure 11.

Likewise the second transistor structure 12 can comprise one or more M0 layer contacts 12b. The M0 layer contact(s) 12b can be connected to a source/drain of the second transistor structure 12 and/or can merge into the source/drain of the second transistor structure 12.

The respective source/drain of the first transistor structure 11 and the second transistor structure 12 can wrap around the respective channel(s) 11a, 12a of the transistor structures 11, 12 in various implementations.

At least one of the top signal routing lines 15 of the set of top signal routing lines can be connected by a respective contact structure to the first transistor structure 11 and/or the second transistor structure 12. For instance, these contact structures can be formed by high aspect-ratio vias.

A possible connection of a top signal routing line 15 to the M0 zero layer contacts 12b of the second transistor structure 12 is illustrated by a dashed box in FIG. 1. The set of top signal routing lines 15 may further be connected by a respective contact structure to a gate of the first transistor structure 11 and/or to a gate of the second transistor structure 12.

The bottom signal routing line 16 can be a line structure which extends in a y-direction, perpendicular to an extension direction of the M0 layer contacts 11b, 12b.

The CFET cell 10 can comprise one or a plurality of bottom signal routing lines 16. For instance, a bottom signal routing line 16 could be arranged on each side of the channel stack, for example, if none of the sides is blocked by a power rail 14.

The CFET cell 10 can further comprise a first power rail 13 arranged below the first tier and connected to the first transistor structure 11 from below. A possible contact between the first power rail 13 and the first transistor structure 11 is illustrated by a trapezoidal structure FIG. 1, but the first power rail 13 could also be connected directly to the first transistor structure 11 from below. The first power rail 13 may be a back-side power rail, and may be connected to the first transistor structure 11 by a back-side contact.

For example, the at least one bottom signal routing line 16 can be arranged above the first power rail 13 and below the first transistor structure 11, e.g., in-between the first power rail 13 and the first transistor structure 11. The bottom signal routing line 16 can be arranged in a space next to the back-side contact of the first power rail 13 which is not occupied by any other structures.

The CFET cell 10 may comprise a second power rail 14 formed in a third metal layer and connected to the second transistor structure 12b from a first side (the right side in FIG. 1). A possible contact between the second power rail 14 and the second transistor structure 12 is illustrated by a dashed box, but the second power rail 14 could also be connected directly to the second transistor structure 12.

For example, a part of the second power rail can be arranged in the second tier to the first side of the second transistor structure; and/or a part of the second power rail is arranged in the first tier to the first side of the first transistor structure.

Alternatively to the example shown in FIG. 1, different arrangements of the first and second power rails 13, 14 are possible. For instance, both power rails 13, 14 can may be arranged below the first tier and can both be connected to the first and second transistor structures 11, 12 from below.

The first power rail 13 may be configured to supply VDD (a supply voltage), e.g., is a VDD rail, and the second power rail 14 may be configured to supply VSS (a ground voltage or negative voltage), e.g., is a VSS rail. For instance, VDD and VSS could also be swapped.

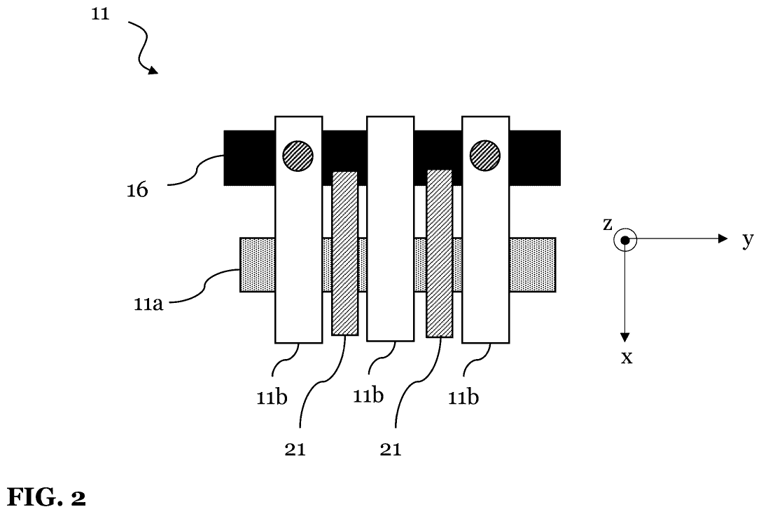

FIG. 2 shows the first transistor structure 11 of the example CFET cell 10 according to the disclosed technology in a top view. For example, FIG. 2 shows a possible arrangement of the first transistor structure 11 of FIG. 1 in the x- and y-direction, as indicated by the Cartesian coordinate system.

The first transistor structure 11 in FIG. 1 comprises gates 21 which are arranged along the direction of the channel (e.g., alternating with source/drain structures). For instance, the gates 21 can wrap around, e.g., fully around all sides, the channel(s) 11a.

The M0 contact structures 11b extend perpendicular to the channel direction and can be connected to and/or merge with respective source or drain (structures) of the first transistor structure 11.

FIG. 2 further shows the bottom signal routing line 16 which is arranged below (in z-direction) the M0 contact structures 11b and is connected to two of the M0 contact structures 11b, as indicated by the two shaded circles.

For example, the bottom signal routing line 16 can be a one-dimensional line structure. In particular, this can mean that it extends along one spatial direction (here: the y-direction) and is spatially confined in all other spatial directions. The bottom signal routing line 16 can thus be configured to route signals along this one spatial direction.

For example, the bottom signal routing line 16 can extend along a direction which is parallel to the channel direction and perpendicular to the gates 21.

The M0 contact structures 11b can also be one-dimensional structures which are arranged perpendicular to the bottom signal routing line 16 and/or the channel(s) 11a.

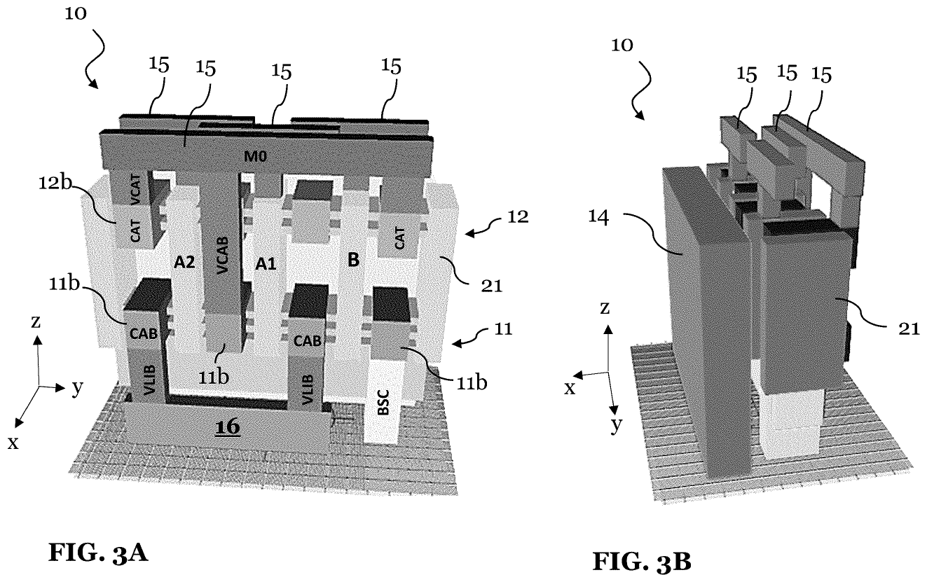

FIGS. 3A and 3B show an example CFET cell 10 according to the disclosed technology in different perspective views (its extension in x-, y- and z-direction, as indicated by the Cartesian coordinate systems in FIGS. 3A and 3B). For example, FIGS. 3A and 3B can show the same CFET cell 10. The CFET cell 10 of FIGS. 3A-B may build on or may be the CFET cell shown in FIG. 1 and/or FIG. 2.

The CFET cell 10 shown in FIGS. 3A and 3B comprises a number of gates 21, referred to as A2, A1 and B as well as a number of M0 layer contacts 11b, 12b of the first and second transistor structures 11, 12, referred to as CAB (contact active bottom) and CAT (contact active top) respectively. For instance, CAB and/or CAT can be one dimensional structures. CAT and CAB can also be referred to as MOAT and MOAB, respectively.

As shown in FIGS. 3A and 3B, one or more top signal routing lines 15 can be connected to a respective M0 layer contact 11b, 12b of the first and second transistor structures 11, 12. These connection can be established via vertical contact structures, e.g., vias, referred to as VCAT and VCAB. The top signal routing lines 15 can be formed in a metal intermediate (Mint) layer.

Likewise, the bottom signal routing line 16 can be connected to the M0 layer contact CAB via vertical contact structures, e.g., vias, referred to as VLIB. The bottom signal routing line 16 can form a (one-dimensional) horizontal local interconnect level (HLI).

Due to this CFET cell 10 design in various implementations, CAT/CAB can become purely one-dimensional structures (all horizontal routing can be removed). As such, in various instances, all signal routing in the CFET cell 10 can be one-dimensional. Such one-dimensional metal levels can be much easier to print and to process than 2D metal levels. Hence, this approach can make the routing in the CFET cell 10 more scalable and easier to manufacture. For example, the one-dimensionality of the bottom signal routing line can allow for narrower lithography pitches when manufacturing the CFET cell 10.

The CFET cell 10 can further comprise a back-side contact (BSC) which connects the first transistor structure 11 to the first power rail (not shown).

FIG. 3B shows the second power rail 14 which is arranged on the first side of the transistor structures 11, 12. In the perspective of FIG. 3A, this second power rail 14 is arranged “behind” the visible structures.

For instance, the bottom signal routing line 16 can provide horizontal routability to the bottom device (the first transistor structure 11) polarity. The top device (the second transistor structure 12) polarity can be brought up to Mint, e.g., connected to the set of top signal routing lines 15, to achieve horizontal routability. In various implementations, with this 3-levels interconnect design, all horizontal routing can be removed from CAT/CAB which can become purely vertical (1D).

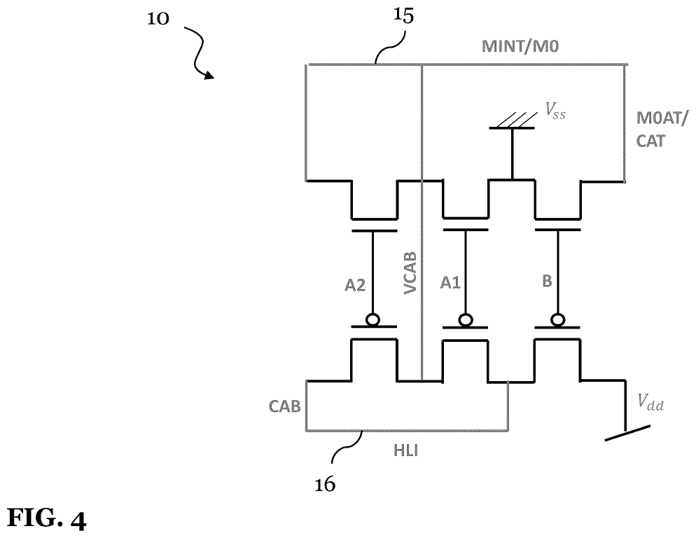

FIG. 4 shows an equivalent circuit diagram of the example CFET cell 10 shown in FIGS. 3A-B.

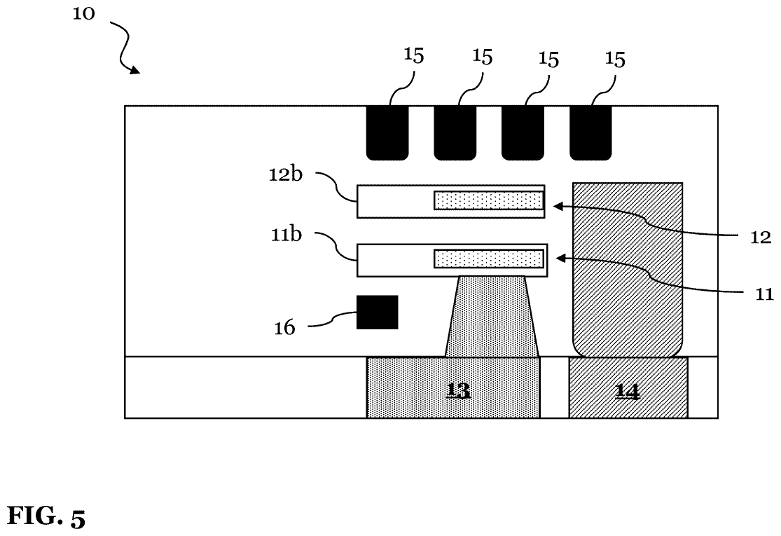

FIG. 5 shows an example CFET cell 10 according to the disclosed technology in a side view. In the example shown in FIG. 5, the second power rail 14 extends vertically to the bottom side of the CFET cell 10.

The top signal routing lines 15 can be arranged side by side. A part of the second power rail can be arranged to (e.g., on) the first side of the set of top signal routing lines 15.

For instance, if the second power rail 14 extends to the bottom side of the CFET cell 10, as shown in FIG. 5, an additional top signal routing line 15 could be formed in the first metal layer above the second tier and to the first side of the set of top signal routing lines 15, and could be connected to the first and/or the second transistor structure(s) 11, 12 from above.

For example, the second power rail 14 can have a width that is equal to or larger than two times a critical dimension of the first metal layer.

In a further example, the top signal routing lines 15 of the set of top signal routing lines and a half of the second power rail 14 can span together a width of the CFET cell 10 that corresponds to a track height of a 3.5 T or 4 T CFET cell 10.

In an alternative design (not shown), the second power rail 14 could also be contacted via one or more top signal routing line(s) 15 (not shown).

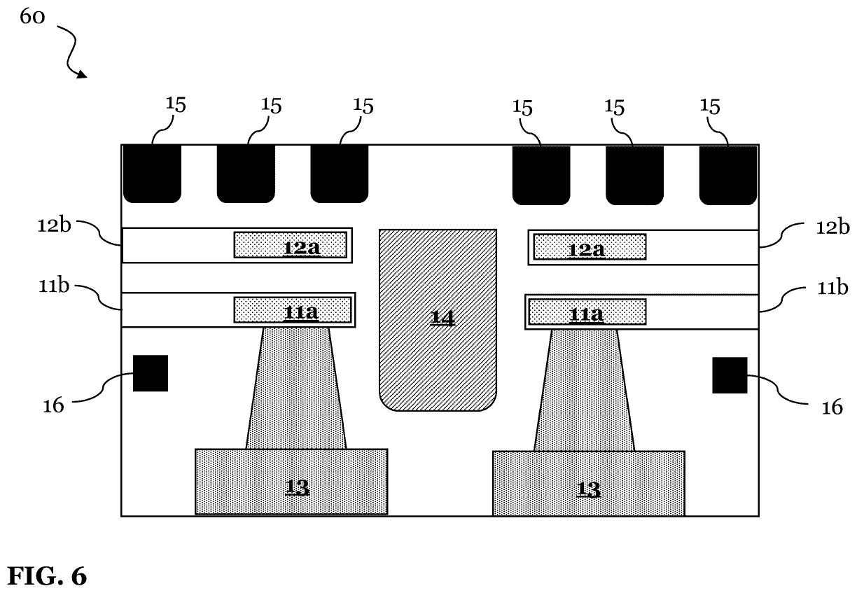

FIG. 6 shows an example CFET device 60 according to the disclosed technology. The CFET device 60 is shown with two CFET cells 10 and in a side view. The two CFET cells 10 are arranged side by side.

In the device 60 shown in FIG. 6, the second power rail 14 is common to both of the two CFET cells 10, e.g., it can be the same power rail for each CFET cell 10. The second power rail 14 can be arranged between the transistor structures 11, 12 of one of the two CFET cells 10 and the transistor structures 11, 12 of the other one of the two CFET cells 10.

In various implementations, the center of the CFET device 60 between the two CFET cells 10 can be configured and/or optimized for power-delivery. Each CFET cell 10 can have at least three top signal routing lines 15. The second power rail 14 may for example, have a width (e.g., in x-direction) that is equal to or larger than two times a critical dimension of the first metal layer, in which the signal routing lines 15 are formed, for instance the Mint layer. The second power rail 14 may further be configured as shown in FIG. 5, e.g., reaching to the bottom of the CFET cell 10.

Due to each bottom signal routing lines 16 being arranged below a respective first transistor structures 11 in various implementations, the size of the CFET device 60 can be reduced, for example, compared to a CFET device 60 with a side-routing architecture.

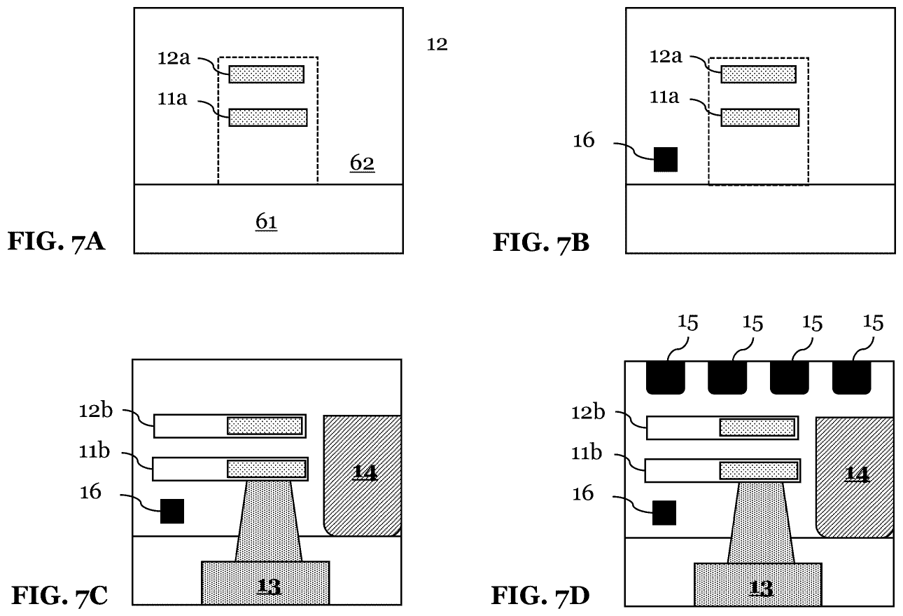

FIGS. 7A-D show various intermediate structures of a method of fabricating a CFET cell according to the disclosed technology.

In various implementations, shown in FIG. 7A, at least a part of the first transistor structure 11 is formed in a first tier of the CFET cell 10, and at least a part of the second transistor structure 12 is formed in a second tier of the CFET cell 10 above the first tier.

For example, the channel(s) 11a, 12a of the first and second transistor structures 11, 12 are formed. For instance, the method can comprise active (channel) patterning of the first and second transistor structures 11, 12.

The channel(s) 11a, 12a can be formed on top of a silicon substrate 61. The channel(s) 11a, 12a can be surrounded by a dielectric layer 62, e.g., a metal oxide layer (MOL).

In various implementations, shown in FIG. 7B, the at least one bottom signal routing line 16 is formed in the second metal layer below the first tier.

For instance, the bottom signal routing line 16 can be formed after active patterning of the channels 11a, 12a and STI planarization.

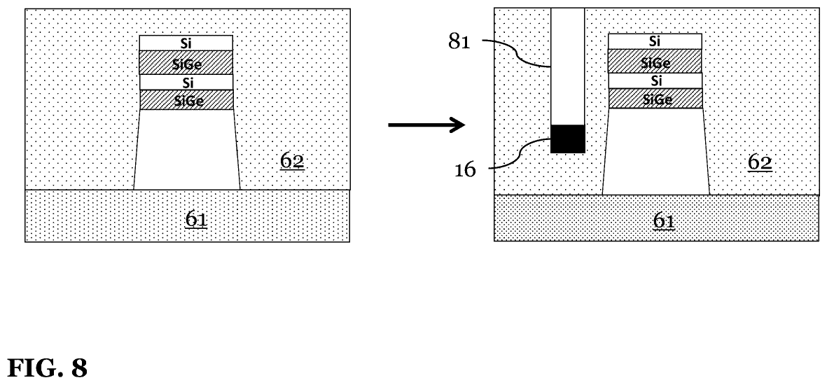

An example of how the bottom signal routing line 16 can be processed is shown in FIG. 8. For instance, the bottom signal routing line 16 can be processed by etching a trench 81 in the dielectric layer 62 of the CFET cell 10 (e.g., next to the channels), and, e.g., subsequently, filling the bottom of the trench 81 with the second metal layer material, e.g., by a suitable liquid metal fill process. After deposition of the second metal layer in the trench 81, this layer can be partially recessed, e.g., by an etching process, in order to confine the second metal layer to the bottom of the trench 81 and below the first tier. This can be carried out for each bottom signal routing line 16 of the CFET cell 10.

The bottom signal routing line 16 could also be formed from the bottom, e.g., by etching and filling the trench 81 from the bottom.

In this way, the signal routing line 16 can form a buried horizontal interconnect (HLI) level which can be arranged next to a back-side contact and/or a silicon base of the transistor structures 11, 12.

In various implementations, shown in FIG. 7C, further structures of the CFET cell can be processed. For instance, the M0 layer contacts 11b, 12b of the first and second transistor structures 11, 12 can be formed, e.g., after the processing of the bottom signal routing line 16. Furthermore, the gate(s) and source/drain(s) of the CFET cell can be formed, e.g., after the processing of the bottom signal routing line 16. Each M0 layer contact 11b, 12b can be connected to a source or a drain of the first and second transistor structures 11, 12.

Furthermore, vertical connections can be formed to connect the bottom signal routing line 16 to the first transistor structure 11, for example, to the M0 layer contacts 11b of the first transistor structure 11.

Further, CFET BSPDN (backside power delivery) processing can be carried out. For example, the first power rail 13 can be processed below the first tier and can be connected to the first transistor structure 11 from below, e.g., via a back side contact structure. In addition, the second power rail 14 can be processed in a third metal layer, e.g., to a first side of the second transistor structure 12 and can be connected to the second transistor structure 12 from the first side. However, alternative arrangements of the first and second power rail 13, 14 are also possible (e.g., both power rails 13, 14 can be processed below the first tier).

In various implementations, shown in FIG. 7D, the set of top signal routing lines 15 are processed in a first metal layer above the second tier.

The top signal routing lines 15 can be connected to the first and the second transistor structure from above (not shown), e.g., by forming vertical connecting structures such as vias.

The method of fabricating the CFET cell 10 do not have to be performed, necessarily, in the order described above and/or shown in FIGS. 7A-D.

In the claims as well as in the description of the disclosed technology, the word “comprising” does not exclude other elements or steps and the indefinite article “a” or “an” does not exclude a plurality. A single element may fulfill the functions of several entities or items recited in the claims. The mere fact that certain measures are recited in the mutual different dependent claims does not indicate that a combination of these measures cannot be used in an advantageous implementation.

What is claimed is:

1. A complementary field effect transistor (CFET) cell, comprising:
a first transistor structure arranged in a first tier;
a second transistor structure arranged in a second tier above the first tier;
a set of top signal routing lines formed in a first metal layer above the second tier and connected to the first and second transistor structures from above the second tier; and
at least one bottom signal routing line formed in a second metal layer below the first tier and connected to the first transistor structure from below the first tier.

2. The CFET cell of claim 1,
wherein the at least one bottom signal routing line is a one-dimensional line structure and/or is configured to route signals along one spatial direction.

3. The CFET cell of claim 1,
wherein the at least one bottom signal routing line extends along a direction which is perpendicular to a lateral extension direction of a gate of the first transistor structure and/or to a lateral extension direction of a gate of the second transistor structure.

4. The CFET cell of claim 1,
wherein the at least one bottom signal routing line is connected to one or more metal zero (M0) layer contacts of the first transistor structure;
wherein each M0 layer contact is connected to a source or a drain of the first transistor structure.

5. The CFET cell of claim 1, further comprising:
a first power rail arranged below the first tier and connected to the first transistor structure from below the first tier.

6. The CFET cell of claim 1, further comprising:
a second power rail formed in a third metal layer and connected to the second transistor structure from a first side.

7. The CFET cell of claim 6,
wherein the second power rail extends vertically to a bottom side or to a top side of the CFET cell.

8. The CFET cell of claim 6,
wherein the top signal routing lines of the set of top signal routing lines are arranged side by side, and a part of the second power rail is arranged on the first side of the set of top signal routing lines.

9. A device comprising two CFET cells of claim 1,
wherein the two CFET cells are arranged laterally side by side.

10. The device of claim 9, wherein a second power rail of the two CFET cells is the same power rail arranged between the transistor structures of one CFET cell and the transistor structures of the other CFET cell.

11. A method of fabricating a complementary field effect transistor (CFET) cell, comprising:
forming a first transistor structure in a first tier;
forming a second transistor structure in a second tier above the first tier;
processing a set of top signal routing lines in a first metal layer above the second tier and connecting the set of top signal routing lines to the first and second transistor structures from above the second tier; and
processing at least one bottom signal routing line in a second metal layer below the first tier and connecting the at least one bottom signal routing line to the first transistor structure from below the first tier.

12. The method of claim 11,
wherein the at least one bottom signal routing line is processed by etching a trench in a dielectric layer of the CFET cell and filling the bottom of the trench with the second metal layer.

13. The method of claim 12,
wherein, to fill the bottom of the trench with the second metal layer, the second metal layer is deposited in the trench and partially recessed in order to confine the second metal layer to the bottom of the trench below the first tier.

14. The method of claim 11, further comprising:
processing one or more metal zero (M0) layer contacts of the first transistor structure, wherein each M0 layer contact is connected to a source or a drain of the first transistor structure; and
connecting the at least one bottom signal routing line to the M0 layer contacts.

15. The method of claim 11, further comprising:
processing a first power rail below the first tier and connecting the first power rail to the first transistor structure from below the first tier.

16. The method of claim 11, further comprising:
processing a second power rail in a third metal layer on a first side of the second transistor structure and connecting the second power rail to the second transistor structure.

17. The method of claim 11,
wherein the at least one bottom signal routing line is a one-dimensional line structure and/or is configured to route signals along one spatial direction.

18. The method of claim 11,
wherein the at least one bottom signal routing line extends along a direction which is perpendicular to a lateral extension direction of a gate of the first transistor structure and/or to a lateral extension direction of a gate of the second transistor structure.

19. The method of claim 16,
wherein the second power rail extends vertically to a bottom side or to a top side of the CFET cell.

20. The method of claim 19,
wherein the top signal routing lines of the set of top signal routing lines are arranged side by side, and a part of the second power rail is arranged on the first side of the set of top signal routing lines.
